(19) United States
(12) Patent Application Publication
(10) Pub. No.: US 2026/0256028 A1
(43) Pub. Date: Aug. 27, 2026

(54) SEMICONDUCTOR PACKAGE AND METHOD FOR MANUFACTURING THE SAME

(71) Applicant: Samsung Electronics Co., Ltd., Suwon-si (KR)

(72) Inventors: Kwang-Soo Kim, Suwon-si (KR); Hohyeuk Im, Suwon-si (KR); Yunseop Shin, Suwon-si (KR)

(21) Appl. No.: 19/545,768

(22) Filed: Feb. 20, 2026

(30) Foreign Application Priority Data
Feb. 24, 2025 (KR) 10-2025-0023416

(51) Int. Cl. H10W 90/28; H10W 20/20; H10W 72/00; H10W 74/10; H10W 90/10

(52) U.S. Cl. CPC H10W 90/28; H10W 20/211; H10W 72/823; H10W 74/111; H10W 90/10

(57) ABSTRACT

A semiconductor package includes a first redistribution layer, an inner chip disposed on the first redistribution layer, first chip terminals connecting the first redistribution layer and the inner chip, a molding layer surrounding the inner chip on the first redistribution layer, a second redistribution layer disposed on the molding layer, the second redistribution layer including first wiring patterns connected to a top surface of the inner chip, conductive posts vertically penetrating the molding layer to connect the first redistribution layer and the second redistribution layer, and a first semiconductor chip mounted on the second redistribution layer. Each of the first chip terminals has a major axis and a minor axis that are parallel to a top surface of the first redistribution layer and perpendicular to each other, and the major axis of the each of the first chip terminals is directed toward a center of the inner chip.

### CROSS-REFERENCE TO RELATED APPLICATIONS

This application claims priority under 35 U.S.C. §119 to Korean Patent Application No. 10-2025-0023416, filed on February 24, 2025, in the Korean Intellectual Property Office, the entire contents of which are hereby incorporated by reference.

### BACKGROUND

With the development of the electronic industry, there is an increasing demand for high functionality, high speed, and miniaturization of electronic components. In response to this trend, a recent packaging technology has progressed toward mounting a plurality of semiconductor chips in one package.

### SUMMARY

In order to realize miniaturization and weight reduction of such electronic components, not only a technique of reducing an individual size of a mounted component, but also a semiconductor package technique of integrating a large number of individual elements into one package are required. In particular, semiconductor packages that handle high-frequency signals are required to achieve not only miniaturization but also excellent electrical characteristics.

In general, though silicon via (TSV) process, a flip chip manner, a wire bonding process, and the like are used to stack a plurality of memory chips on a package substrate. However, the TSV process has a problem in that the process is complicated and the cost is excessive, and a need for a process for solving the problem may arise.

Semiconductor packages include integrated circuit chips in a form suitable for use in electronics. Semiconductor packages typically mount semiconductor chips on a printed circuit board (PCB) and electrically connect them using bonding wires or bumps. With the recent development of the electronics industry, semiconductor packages have been developed in various ways with the goal of miniaturization, weight reduction, and reduction of manufacturing costs. In addition, as applications expand to mass storage devices and the like, various type of semiconductor packages are appearing.

Implementations according to the present disclosure provides a semiconductor package with improved structural stability.

Implementations according to the present disclosure provides a method for manufacturing a semiconductor package with less occurrence of process failure.

In general, in some aspects, the present disclosure provides a semiconductor package that can include: a first redistribution layer; an inner chip disposed on the first redistribution layer; first chip terminals connecting the first redistribution layer and the inner chip; a molding layer surrounding the inner chip on the first redistribution layer; a second redistribution layer disposed on the molding layer, the second redistribution layer including first wiring patterns connected to a top surface of the inner chip; conductive posts vertically penetrating the molding layer to connect the first redistribution layer and the second redistribution layer; and a first semiconductor chip mounted on the second redistribution layer. Each of the first chip terminals has a first major axis and a first minor axis that are parallel to a top surface of the first redistribution layer and perpendicular to each other. The first major axis of the each of the first chip terminals is directed toward a center of the inner chip, in a plan view.

In general, in some aspects, the present disclosure provides a semiconductor package that can include: a package substrate; an interposer substrate mounted on the package substrate; a first semiconductor chip disposed on the interposer substrate; and a chip stack disposed on the interposer substrate and horizontally spaced apart from the first semiconductor chip, the chip stack includes second semiconductor chips that are vertically stacked. The interposer substrate comprises: a first redistribution layer, a top surface of the first redistribution layer comprising a first region in which first pads are provided, and a second region surrounding the first region and in which second pads are provided; an inner chip disposed on the first redistribution layer and mounted to the first pads; a molding layer surrounding the inner chip on the first redistribution layer; a second redistribution layer disposed on the molding layer, the second redistribution layer comprising a wiring pattern connected to an active surface of the inner chip; and conductive posts vertically penetrating the molding layer to connect the first redistribution layer and the second redistribution layer, the conductive posts are connected to the second pads. Each of the first pads has an elliptical planar shape or a rectangular planar shape. Each of the second pads has a circular planar shape or a square planar shape.

In general, in some aspects, the present disclosure provides a semiconductor package that can include: a first redistribution layer, a top surface of the first redistribution layer comprising a first region in which first pads are provided, and a second region surrounding the first region and in which second pads are provided; an inner chip disposed on the first redistribution layer and mounted to the first pads; chip terminals connecting the first pads and the inner chip; a molding layer surrounding the inner chip on the first redistribution layer; conductive posts vertically penetrating the molding layer and connected to the second pads of the first redistribution layer; and a second redistribution layer disposed on the molding layer and comprising a wiring pattern connected to an active surface of the inner chip and the conductive posts. Each of the first pads has a major axis and a minor axis parallel to the top surface of the first redistribution layer and perpendicular to each other, and the major axis of the each of the first pads is directed toward a center of the inner chip, in a plan view. Each of the second pads has a circular planar shape or a square planar shape.

### BRIEF DESCRIPTION OF THE DRAWINGS

FIG. 1 is a cross-sectional view illustrating an example of a semiconductor package.

FIG. 2 is a plan view illustrating an example of an interposer substrate of a semiconductor package.

FIG. 3 is a plan view illustrating a first direction and a second direction on an example of an interposer substrate.

FIGS. 4 to 6 are plan views illustrating an example of an interposer substrate of a semiconductor package.

FIG. 7 is a plan view illustrating an example of an inner chip of a semiconductor package.

FIGS. 8 to 10 are plan views illustrating an example of an interposer substrate and an example of an inner chip of a semiconductor package.

FIG. 11 is a plan view illustrating an example of an interposer substrate of a semiconductor package.

FIGS. 12 and 13 are cross-sectional views illustrating an example of a semiconductor package.

FIGS. 14 to 22 are drawings illustrating an example of a method of fabricating a semiconductor package.

### DETAILED DESCRIPTION

Example implementations of the present disclosure will now be described more detail with reference to the accompanying drawings, in which example implementations are shown.

A semiconductor package according to some implementations is described with reference to the drawings.

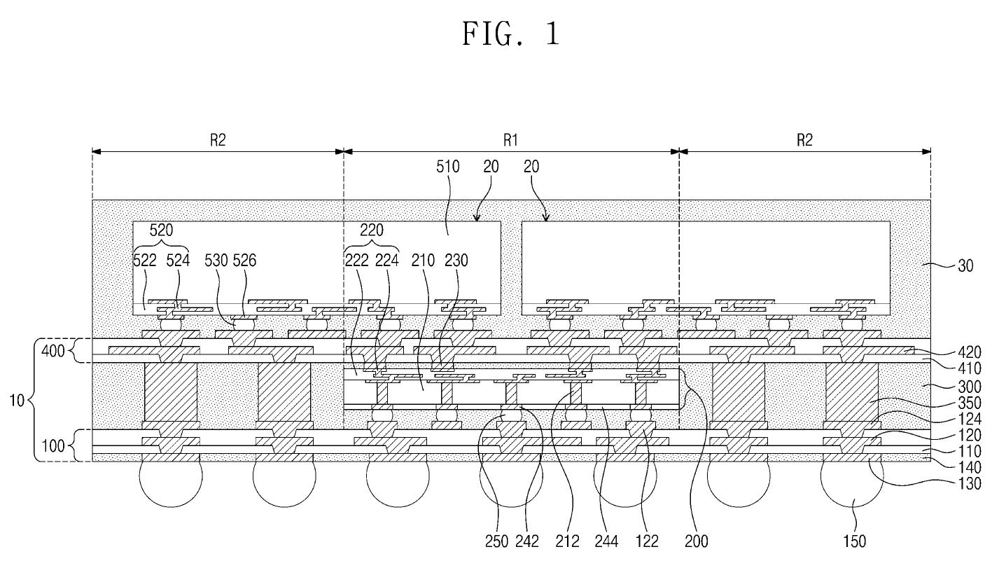

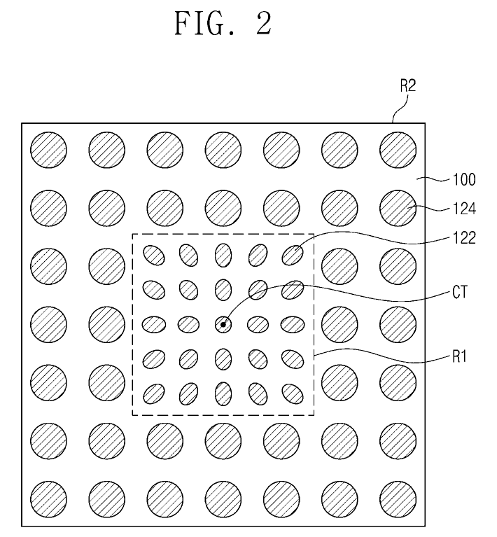

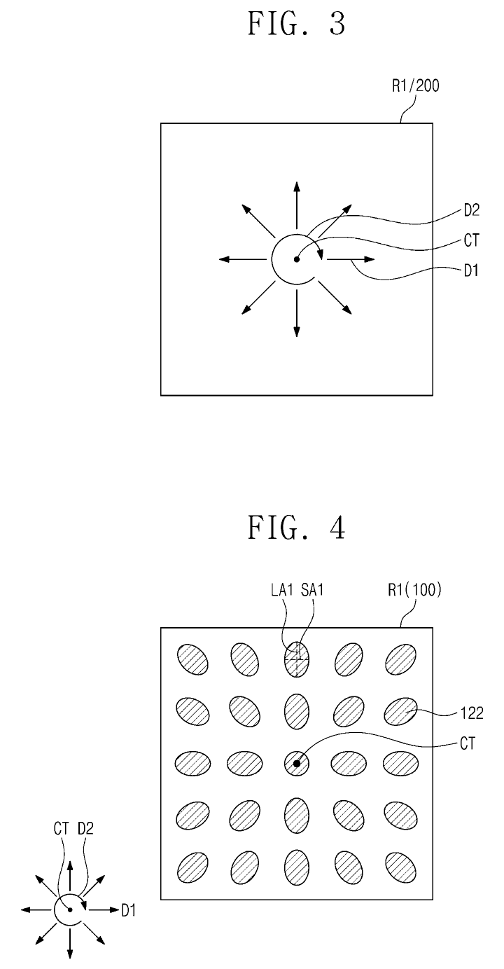

FIG. 1 is a cross-sectional view illustrating a semiconductor package according to some implementations. FIG. 2 is a plan view illustrating an interposer substrate of a semiconductor package according to some implementations. FIG. 2 corresponds to a plan view of the first redistribution layer of the interposer substrate viewed from above. FIG. 3 is a plan view for explaining the first direction and the second direction on the interposer substrate.

Referring to FIG. 1, an interposer substrate 10 may be provided. The interposer substrate 10 may include a first redistribution layer 100, an inner chip 200, a first molding layer 300, conductive posts 350, and a second redistribution layer 400.

The first redistribution layer 100 may include at least one first substrate wiring layer comprising a first substrate insulation pattern 110 and a first substrate wiring pattern 120 on the first substrate insulation pattern 110.

The first substrate insulation pattern 110 may comprise an insulating polymer or a photosensitive insulating material (PID). For example, the photosensitive polymer may include at least one of a photosensitive polyimide, a polybenzoxazole (PBO), a phenolic polymer, or a benzocyclobutene-based polymer.

The first substrate wiring patterns 120 may be provided on the first substrate insulation pattern 110. The first substrate wiring patterns 120 may extend horizontally on the first substrate insulation pattern 110. The first substrate wiring patterns 120 may be provided on a top surface of the first substrate insulation pattern 110. The first substrate wiring patterns 120 may protrude from the top surface of the first substrate insulation pattern 110. At least a portion of the first substrate wiring patterns 120 may extend horizontally on the first substrate insulation pattern 110. As above, the first substrate wiring patterns 120 may be a pad portion or a wiring portion of the first substrate wiring layer. That is, the first substrate wiring patterns 120 may be patterns for horizontal redistribution in the first redistribution layer 100. The first substrate wiring patterns 120 may comprise a conductive material. For example, the first substrate wiring patterns 120 may include a metal such as copper (Cu).

One of the first substrate wiring patterns 120 of the first substrate wiring layers may be electrically connected with another adjacent one of the first substrate wiring pattern 120 of the first substrate wiring layers. The first substrate wiring patterns 120 on one of the first substrate insulation patterns 110 may be covered by another one of the first substrate insulation patterns 110.

The first substrate wiring patterns 120 may have a damascene structure. For example, each or at least some of the first substrate wiring patterns 120 may comprise a via on a bottom surface thereof. The via may provide a vertical wiring in the first substrate wiring layers. For example, the via may extend from a bottom surface of one of the first substrate wiring patterns 120, and may penetrate through the first substrate insulation pattern 110 to be connected to another one of the first substrate wiring patterns 120 provided therebelow. Alternatively, the via of the first substrate wiring patterns 120 of the lowermost first substrate wiring layer may extend from the bottom surface of the first substrate wiring patterns 120, and may penetrate through the first substrate insulation pattern 110 to be connected to a top surface of an external pads 130 to be described later. An upper portion of the first substrate wiring patterns 120 located on the first substrate insulation pattern 110 may be a head portion used as a horizontal wiring or pad, and the via of the first substrate wiring pattern 120 may be a tail portion. A width of the tail portion may be less than that of the head portion. The width of the tail portion may decrease as a distance from the head portion of the first substrate wiring patterns 120. In other words, the tail portion may have a tapered shape. Each or at least some of the first substrate wiring patterns 120 may have a T-shape.

At least portions 122, 124 of the first substrate wiring patterns 120 of the uppermost first substrate wiring layer may serve as redistribution pads to which an inner chip 200 or a conductive post 350 described later is connected. The redistribution pads 122, 124 will be described in more detail with reference to FIG. 2.

Referring to FIGS. 1 and 2, a top surface of the first redistribution layer 100 may comprise a first region R1 and a second region R2. The first region R1 may be a region in which the inner chip 200 is mounted on the first redistribution layer 100. The second region R2 may be a remaining region except for the first region R1on the top surface of the first redistribution layer 100, and may be a region in which the conductive post 350 is connected to the first redistribution layer 100. A planar shape of the first region R1 may depend on a planar shape of the inner chip 200. The first region R1 may be provided in a center region of the first redistribution layer 100. The second region R2 may surround the first region R1, in a plan view. The second region R2 may be provided on an edge region of the first redistribution layer 100.

At least portions 122, 124 of the first substrate wiring patterns 120 of the uppermost first substrate wiring layer, i.e., the redistribution pads 122, 124, may be exposed on the top surface of the first redistribution layer 100. Hereinafter, for convenience of description, the redistribution pads 122 provided on the first region R1 are defined as first pads 122, and the redistribution pads 124 provided on the second region R2 are defined as second pads 124.

The first pads 122 may be spaced apart from each other on the first region R1. The first pads 122 may be electrically connected to wiring in the first redistribution layer 100. The first pads 122 may be pads for mounting the inner chip 200.

As shown in FIG. 2, the first pads 122 may have a planar shape in which a width in one direction is greater than that in other direction. More specifically, each of the first pads 122 may have a major axis (see LA1 of FIG. 4) and a minor axis (see SA1 of FIG. 4), in a plan view. The major axis LA1 and the minor axis SA1 may be parallel to the top surface of the first redistribution layer 100. In a plan view, the major axis LA1 of each of the first pads 122 may be directed toward a center CT of the first region R1. In FIG. 2, the first region R1 may be a region vertically overlapping with the inner chip 200 on the top surface of the first redistribution layer 100, and it is defined that the center CT of the first region R1 is also at the same position as the center CT of an inner chip 200, in a plan view. Hereinafter, for convenience of description, as shown in FIG. 3, a direction away from the center CT of the first region R1, that is, a radial direction from the center CT the first region R1 is defined as a first direction D1, and a direction rotating about the center CT of first region R1 is defined as a second direction D2. In other words, the second direction D2 may be a direction perpendicular to the first direction D1 at each position. The first pads 122 will be described in more detail with reference to FIGS. 4 to 6 together.

FIGS. 4 to 6 are plan views illustrating an interposer substrate of a semiconductor package according to some implementations. FIGS. 4 to 6 correspond to the first region R1 of the first redistribution layer 100 of the interposer substrate 10. FIGS. 4 to 6 show the first region R1 of the first redistribution layer 100 overlapping the inner chip 200.

Referring to FIGS. 1 to 4, the major axis LA1 of each of the first pads 122 may be along the first direction D1, and the minor axis SA1 of each of first pads 122 may be along the second direction D2. The minor axis SA1 of each of the first pads 122 may be arranged along a concentric circle relative to the center CT of the first region R1. A ratio of the major axis LA1 and the minor axis SA1 of each of the first pads 122 may be 1.1:1 to 2.5:1. Lengths of the minor axes SA1 of the first pads 122 may be uniform. For example, the lengths of the minor axes SA1 of the first pads 122 may be equal to each other. Lengths of the major axes LA1 of the first pads 122 may increase as the first pads 122 are positioned farther away from the center CT of the first region R1. A planar shape of the each of the first pads 122 may be an elliptical shape having the major axis LA1 and the minor axis SA1.

In some implementations, as shown in FIG. 5, the planar shape of the each of the first pads 122 may be a rectangle or polygon with rounded corners.

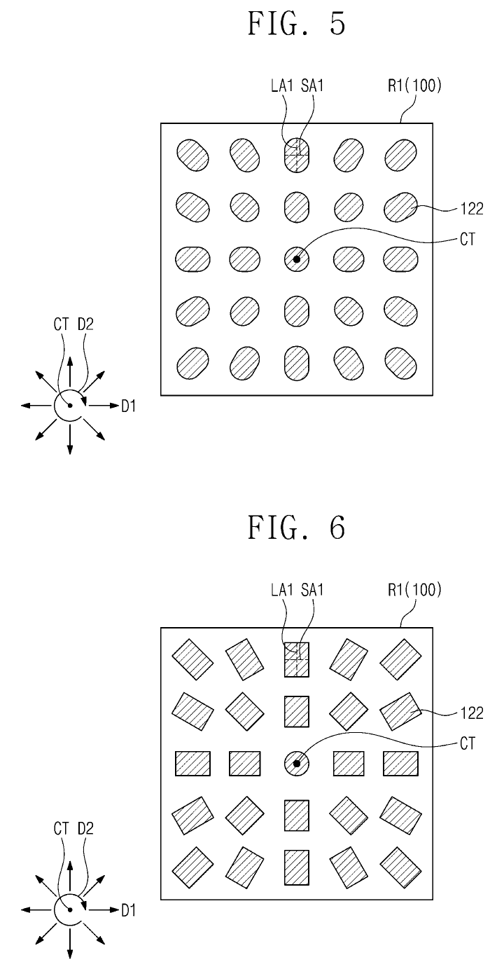

In some implementations, as shown in FIG. 6, the planar shape of the each of the first pads 122 may be a rectangle or polygon having the major axis LA1 and the minor axis SA1. Hereinafter, the description will continue based on some implementations of FIG. 4. For the first pad 122 provided on the center CT of the first region R1 among the first pads 122, the length of the major axis LA1 and the length of the minor axis SA1 of the first pad 122 provided on the center CT of the first region R1 may be equal to each other. That is, the first pad 122 provided on the center CT of the first region R1 may have a circular planar shape.

Referring again to FIGS. 1 and 2, the second pads 124 may be spaced apart from each other on the second region R2. The second pads 124 may be electrically connected to the wiring in the first redistribution layer 100. The second pads 124 may be pads in which the conductive posts 350 are connected. Each of the second pads 124 may have a circular planar shape. A width of the second pad 124 may be greater than that of the first pad 122. In some examples, the width of the second pads 124 may be greater than the length of the major axis LA1 of the first pad 122.

First seed/barrier layers may be provided between the first substrate wiring patterns 120 and the first substrate insulation pattern 110. Each of the first seed/barrier layers may cover a bottom surface of one of the first substrate wiring patterns 120. The first seed/barrier layers may conformally cover the bottom surface of the first substrate wiring patterns 120. When the first seed/barrier layers are used as a seed layer, the first seed/ barrier layers may include a metal such as gold (Au). When the first seed/barrier layers are used as a barrier layer, the first seed/ barrier layers may include a metal such as titanium (Ti) and tantalum (Ta), or may include a metal nitride such as titanium nitride (TiN) and tantalum nitride (TaN). The first seed/barrier layers may not be provided.

Although FIG. 1 illustrates the first redistribution layer 100 as having two first substrate wiring layers, in some implementations, the first redistribution layer 100 may comprise one first substrate wiring layer or at least three first substrate wiring layers. Hereinafter, the description will continue based on some implementations of FIG. 1.

The first redistribution layer 100 may comprise a pad layer provided below the lowermost first substrate wiring layer. The pad layer may comprise a substrate protection layer 140 and external pads 130 in the substrate protection layer 140.

The external pads 130 may be provided on a bottom surface of the lowermost first substrate wiring layer. The external pads 130 may be electrically connected with the first substrate wiring patterns 120 of the lowermost first substrate wiring layer. For example, the tail portion of the first substrate wiring patterns 120 may penetrate the first substrate insulation pattern 110 and be connected to a top surface of the external pads 130. The external pads 130 may serve as pads to which external terminals 150 are connected. The external pads 130 may comprise a conductive material. For example, the external pads 130 may comprise a metal such as copper (Cu).

The substrate protection layer 140 may be provided on the bottom surface of the lowermost first substrate wiring layer. The substrate protection layer 140 covers the bottom surface of the lowermost first substrate wiring layer and may surround the external pads 130. For example, a bottom surface of the external pads 130 may be exposed on a bottom surface of the substrate protection layer 140. The bottom surface of the external pads 130 and the bottom surface of the substrate protection layer 140 may be coplanar. The substrate protection layer 140 may comprise a material different from the first substrate insulation pattern 110. For example, the substrate protection layer 140 may comprise a molding member. For example, the molding member may comprise an insulating polymer material such as a photosensitive polymer, an epoxy molding compound (EMC) or an Ajinomoto build-up film (ABF).

The external terminals 150 may be provided on the bottom surface of the external pads 130 that are exposed. The external terminals 150 may comprise solder balls or solder bumps. The semiconductor package may be provided in a form of a ball grid array (BGA), a fine ball-grid array (FBGA), or a land grid array (LGA) according to a type and a disposition of the external terminals 150.

In some implementations, the pad layer may not be provided. In this case, the first substrate wiring patterns 120 of the lowermost first substrate wiring layer may be used as lower pads of the first redistribution layer 100. For example, the first substrate wiring patterns 120 may be exposed on the bottom surface of the first substrate insulation pattern 110, and the external terminals 150 may be provided on the exposed bottom surfaces of the second substrate wiring patterns 120.

The inner chip 200 may be disposed on the first redistribution layer 100. The inner chip 200 may be disposed on the first region R1 of the first redistribution layer 100. The inner chip 200 may comprise a front surface and a rear surface. Hereinafter, the front surface may be defined as a surface of a semiconductor chip, which is an active surface with an integrated device, and on which interconnection wires or pads are formed, and the rear surface may be defined as an opposite surface of the front surface. The rear surface of the inner chip 200 may face the first redistribution layer 100. That is, the inner chip 200 may be disposed on the first redistribution layer 100 in a face up manner. The inner chip 200 may comprise a bridge chip, a passive device chip, or an integrated voltage regulator (IVR) chip. A coefficient of thermal expansion of the inner chip 200 may be different from that of the first redistribution layer 100. The thermal expansion coefficient of the inner chip 200 may be less than the that of first redistribution layer 100. Hereinafter, the inner chip 200 will be described on the basis that the inner chip 200 is a bridge chip.

The inner chip 200 may comprise a semiconductor substrate. For example, the first base layer 210 may be a semiconductor substrate, such as a semiconductor wafer. The first base layer 210 may be a silicon (Si) substrate, a silicon-on-insulator (SOI) substrate, a germanium (Ge) substrate, a germanium-on-insulating (GOI) substrate, a silicon-germanium (SiGe) substrate, a group 3-5 semiconductor substrate or a substrate of an epitaxial thin film formed by performing selective epitaxial growth (SEG). The first base layer 210 may comprise, for example, at least one of silicon (Si), germanium (Ge), silicon-germanium (SiGe), gallium arsenide (GaAs), indium gallium arsenide (InGaAs), aluminum gallium arsenide (AlGaAs), or mixtures thereof.

In some implementations, when the inner chip 200 comprises a passive device chip or an IVR chip, the passive device or an integrated circuit may be provided on an active surface, i.e. a top surface, of the first base layer 210.

A first wiring layer 220 may be disposed on the top surface of the first base layer 210. For example, the first wiring layer 220 may comprise a first chip insulation pattern 222 and a first chip wiring pattern 224, which are formed on the top surface of the first base layer 210. The first wiring layer 220 may comprise a circuit pattern or a protective layer as necessary.

The first chip insulation pattern 222 may comprise an insulating material. For example, the first chip insulation pattern 222 may comprise silicon oxide (SiO), silicon nitride (SiN), silicon oxynitride (SiON), silicon carbonitride (SiCN), or an insulating polymer. Alternatively, the first chip insulation pattern 222 may include an insulating polymer or a photosensitive insulating material (PID). For example, the photosensitive insulating material may include at least one of a photosensitive polyimide, a polybenzoxazole, a phenolic polymer, and a benzocyclobutene-based polymer.

The first chip wiring pattern 224 may be provided in the first chip insulation pattern 222. The first chip wiring pattern 224 may electrically connect between semiconductor chips 20. The first chip wiring pattern 224 may comprise a conductive material. For example, the first chip wiring pattern 224 may comprise copper (Cu) or aluminum (Al).

Although the first chip insulation pattern 222 is illustrated as one layer in FIG. 1, in some implementations, the first chip insulation pattern 222 may comprise a plurality of insulating layers, and the first chip wiring pattern 224 may be a wiring pattern provided in the plurality of insulating layers.

The inner chip 200 may include chip bumps 230 provided on a top surface of the inner chip 200. The chip bumps 230 may be disposed on the top surface of the inner chip 200, i.e., a top surface of first wiring layer 220. That is, the chip bumps 230 may protrude from the top surface of the inner chip 200. In some implementations, the chip bumps 230 may be a part of the first chip wiring pattern 224 and may be provided in the first chip insulation pattern 222. In this case, the chip bumps 230 may be exposed on a top surface of the first chip insulation pattern 222. The chip bumps 230 may be connected with the first chip wiring pattern 224 of the first wiring layer 220. At least one of the chip bumps 230 may be electrically connected with another one of the chip bumps 230 through the first chip wiring pattern 224. FIG. 1 shows only a portion of the first chip wiring pattern 224, and the chip bumps 230 are not electrically floating with each other.

The inner chip 200 may comprise chip vias 212 and chip back pads 242. The chip vias 212 may vertically penetrate the first base layer 210 and be connected to the first wiring layer 220. The chip vias 212 may be exposed to an inactive surface of the first base layer 210, i.e., to a bottom surface of first base layer 210. The chip vias 212 may comprise a conductive material. For example, the chip vias 212 may comprise a metal material such as copper (Cu) or tungsten (W).

Chip back pads 242 may be disposed on the bottom surface of the first base layer 210. Each of the chip back pads 242 may be coupled with one of the chip vias 212 on the bottom surface of the first base layer 210. The chip back pads 242 may include a conductive material. For example, the chip back pads 242 may comprise a metal material such as copper (Cu) or tungsten (W).

In a plan view, locations of the chip back pads 242 may correspond to locations of the first pads 122 of the first redistribution layer 100. A planar shape of the each of the chip back pads 242 may be substantially the same or similar to the planar shape of the each of the first pads 122.

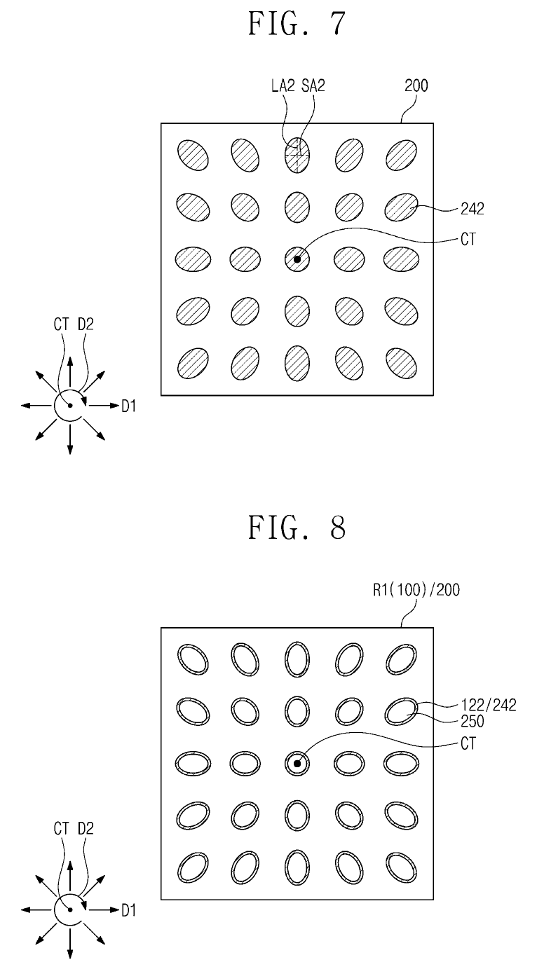

FIG. 7 is a plan view illustrating an inner chip of a semiconductor package according to some implementations. FIG. 7 illustrate the bottom surface of the inner chip 200. The chip back pads 242 will be described in more detail with reference to FIG. 7 together.

Referring to FIGS. 1 and 7, the chip back pads 242 may be spaced apart from each other on the bottom surface of the inner chip 200. The chip back pads 242 may be electrically connected to the first wiring layer 220 through the chip vias 212. The chip back pads 242 may be pads for mounting the inner chip 200 to the first redistribution layer 100.

The chip back pads 242 may comprise the planar shape in which a width in one direction is greater than that in other direction. More specifically, each of the chip back pads 242 may have a major axis LA2 and a minor axis SA2, in a plan view. The major axis LA2 and the minor axis SA2 may be parallel to the bottom surface of the inner chip 200. In a plan view, the major axis LA2 of the each of the chip back pads 242 may be directed toward the center CT of the inner chip 200. The major axis LA2 of the each of the chip back pads 242 may be along the first direction D1, and the minor axis SA2 of the each of chip back pads 142 may be along the second direction D2. The minor axis SA2 of the each of the chip back pads 242 may be arranged along a concentric circle relative to the center CT of the inner chip 200. A ratio of the major axis LA2 and the minor axis SA2 of the each of the chip back pads 242 may be 1.1:1 to 2.5:1. Lengths of the minor axes SA2 of the chip back pads 242 may be uniform. For example, the lengths of the minor axes SA2 of the chip back pads 242 may be equal to each other. Lengths of the major axes LA2 of the chip back pads 242 may increase as the chip back pads 242 are positioned farther away from the center CT of the inner chip 200. A planar shape of the each of the chip back pads 242 may be an elliptical shape having the major axis LA2 and the minor axis SA2. In some implementations, the planar shape of the each of the chip back pads 242 may be a rectangle or polygon with rounded corners. In some implementations, the planar shape of the each of the chip back pads 242 may be rectangular or polygonal with the major axis LA2 and the minor axis SA2. For the chip back pad 242 provided on the center CT of the inner chip 200 among the chip back pads 242, the length of the major axis LA2 and the length of the minor axis SA2 of the chip back pad 242 provided on the center CT of the inner chip 200 may be equal to each other. That is, the chip back pad 242 provided on the center CT of the inner chip 200 may have a circular planar shape.

Referring again to FIG. 1, a back protective layer 244 may be disposed on the bottom surface of the first base layer 210. The back protective layer 244 may cover the bottom surface of the first base layer 210. The back protective layer 244 may surround the chip back pads 242. In this case, a bottom surface of the back protective layer 244 and bottom surfaces of the chip back pads 242 may be substantially flat and coplanar. The back protective layer 244 may comprise an insulating material. For example, the back protective layer 244 may comprise silicon oxide (SiO), silicon nitride (SiN), or silicon oxynitride (SiON). The back protective layer 244 may not be provided.

The inner chip 200 may be mounted on the first redistribution layer 100. For example, the inner chip 200 may be mounted on the first redistribution layer 100 in a flip chip manner. More particularly, the inner chip 200 may be electrically connected to the first pads 122 of the first redistribution layer 100 through inner chip terminals 250. The inner chip terminals 250 may be provided between the chip back pads 242 and the first pads 122. The inner chip 200 may be electrically connected to the first redistribution layer 100 through inner chip terminals 250. As the inner chip 200 is mounted using the inner chip terminals 250, the inner chip 200 may be spaced apart from the top surface of the first redistribution layer 100. The inner chip terminals 250 may comprise conductive bumps, solder balls, or solder bumps.

When the inner chip terminals 250 are coupled to the first pads 122 and the chip back pads 242 by a reflow process, planar shapes of the inner chip terminals 250 may conform to the planar shapes of the first pads 112 and the planar shapes of the chip back pads 242.

FIG. 8 is a plan view illustrating an interposer substrate of a semiconductor package according to some implementations. FIG. 8 shows the top surface of the first redistribution layer 100 and the bottom surface of the inner chip 200 on a same plane. The chip back pads 242 will be described in more detail with reference to FIG. 8 together.

Referring to FIG. 8, the inner chip terminals 250 may be disposed spaced apart from each other between the first redistribution layer 100 and the inner chip 200. The inner chip terminals 250 may electrically connect the inner chip 200 to the first redistribution layer 100.

The inner chip terminals 250 may have the planar shape in which a width in one direction is greater than that in other direction. More specifically, each of the inner chip terminals 250 may have a major axis and a minor axis, in a plan view. In a plan view, the major axis of the each of the inner chip terminals 250 may be directed toward the center CT of the inner chip 200. The major axis of the each of the inner chip terminals 250 may be along the first direction D1, and the minor axis of the each of inner chip terminals 250 may be along the second direction D2. The minor axis of the each of the inner chip terminals 250 may be arranged along a concentric circle relative to the center CT of the inner chip 200. A ratio of the major axis and the minor axis of the each of the inner chip terminals 250 may be 1.1:1 to 2.5:1. Lengths of the minor axes of the inner chip terminals 250 may be uniform. The lengths of the major axes of the inner chip terminals 250 may increase as the inner chip terminals 250 are positioned farther away from the center CT of the inner chip 200. The planar shape of the each of the inner chip terminals 250 may be an elliptical shape having the major axis and the minor axis. For the inner chip terminal 250 provided on the center CT of the inner chip 200 among the inner chip terminals 250, the length of the major axis and the length of the minor axis of the inner chip terminal 250 provided on the center CT of the inner chip 200 may be equal to each other. That is, the inner chip terminal 250 provided on the center CT of the inner chip 200 may have a circular planar shape.

In some implementations, the first pads 122 and the chip back pads 242 may have an elliptical planar shape with the major axis in a direction directed toward the center CT of the inner chip 200. Even if the first pads 122 and the chip back pads 242 are misaligned by the contraction or expansion of the first redistribution layer 100 and the inner chip 200, the first pads 112 and the chip back pads 242 may overlap each other. That is, the inner chip terminals 250 may not be disconnected from the first pads 122 or the chip back pads 242 despite misalignment of the first pads 122 and the chip back pads 142. Therefore, the semiconductor package with improved structural stability may be provided. A temperature range in which the semiconductor package may be driven or a temperature range of a process performed in a manufacturing process of the semiconductor package may also be increased. This will be described in more detail later with a method of fabricating a semiconductor package.

Referring again to FIG. 1, the conductive posts 350 may be disposed on the first redistribution layer 100. The conductive posts 350 may be disposed on the second region R2 of the first redistribution layer 100. For example, the conductive posts 350 may be disposed horizontally spaced apart from the inner chip 200. The conductive posts 350 may be disposed on the second pads 124 of the first redistribution layer 100. The conductive posts 350 may connect the first redistribution layer 100 and the second redistribution layer 400 described later. That is, the conductive posts 350 may be vertical connection terminals. Each of the conductive posts 350 may have a pillar shape that extends in a vertical direction with respect to the top surface of the first redistribution layer 100. In some implementations, the conductive posts 350 may be provided in various forms for a vertical connection. A width of the conductive posts 350 may be constant relative to the vertical direction. That is, each of the conductive posts 350 may have a pillar shape with a constant width. Unlike shown in FIG. 1, the width of the conductive posts 350 may decrease as a distance toward the first redistribution layer 100. Top surfaces of the conductive posts 350 and the top surface of the chip bumps 230 of the inner chip 200 may be provided in a same level. The conductive posts 350 may comprise a conductive material. For example, the conductive posts 350 may comprise a metal material such as copper (Cu) or tungsten (W).

Each of the conductive posts 350 may comprise a seed layer surrounding a side surface thereof. The seed layers may extend to a bottom surface of the conductive posts 350. The seed layers may conformally cover the bottom surface and the side surface of conductive posts 350. The seed layers may comprise a metal such as gold (Au).

A first molding layer 300 may be provided on the first redistribution layer 100. The first molding layer 300 may surround the inner chip 200 and the conductive posts 350 on the first redistribution layer 100. The first molding layer 300 may cover the first wiring layer 220 of the inner chip 200. In this case, the first molding layer 300 may surround the chip bumps 230 of the inner chip 200. The chip bumps 230 may not be covered by the first molding layer 300 and may be exposed on a top surface of the first molding layer 300. The top surface of first molding layer 300, the top surfaces of chip bumps 230, and the top surfaces of conductive posts 350 may be substantially flat and coplanar. The first molding layer 300 may comprise a molding member. The molding member may comprise, for example, an insulating polymeric material such as an epoxy molding compound (EMC) or an Ajinomoto build-up film (ABF).

The second redistribution layer 400 may be provided on the inner chip 200, the conductive posts 350, and the first molding layer 300. The second redistribution layer 400 may be in direct contact with the top surfaces of the chip bumps 230 of the inner chip 200, the top surfaces of conductive posts 350, and the top surface of first molding layer 300.

The second redistribution layer 400 may include at least one second substrate wiring layer. The second substrate wiring layer may include a second substrate insulation pattern 410 and second substrate wiring patterns 420 in the second substrate insulation pattern 410. When a plurality of second substrate wiring layers is provided, one of the second substrate wiring patterns 420 may be electrically connected with another one adjacent of the second substrate wiring patterns 420 of the second substrate wiring layer.

The second substrate insulation pattern 410 may comprise an insulating polymer or a photosensitive insulating material (PID). For example, the photosensitive polymer may comprise at least one of a photosensitive polyimide, a polybenzoxazole (PBO), a phenolic polymer, and a benzocyclobutene-based polymer.

The second substrate wiring patterns 420 may be provided on the second substrate insulation pattern 410. The second substrate wiring patterns 420 may extend horizontally on the second substrate insulation pattern 410. The second substrate wiring patterns 420 may be provided on a top surface of the second substrate insulation pattern 410. The second substrate wiring patterns 420 may protrude from the top surface of the second substrate insulation pattern 410. The second substrate wiring patterns 420 may be covered by another one of the second substrate insulation patterns 420. The second substrate wiring patterns 420 provided in an uppermost second substrate wiring layer may serve as a substrate pad to which the semiconductor chips 20 described later are connected. As above, the second substrate wiring patterns 420 may be a pad portion or a wiring portion of the second substrate wiring layer. That is, the second substrate wiring patterns 420 may be patterns for horizontal redistribution in the second redistribution layer 400. The second substrate wiring patterns 420 may comprise a conductive material. For example, the second substrate wiring patterns 420 may comprise a metal such as copper (Cu).

The second substrate wiring patterns 420 may have a damascene structure. For example, the second substrate wiring patterns 420 may comprise a via on a bottom surface thereof. The via may vertically connect the second substrate wiring patterns 420 of the second substrate wiring layers adjacent to each other. For example, the via may extend from a bottom surface of the second substrate wiring patterns 420, and may penetrate through the second substrate insulation pattern 410 to be connected to another one of the second substrate wiring patterns 420 provided therebelow. Alternatively, the via may connect the conductive posts 350 with the second substrate wiring patterns 420 of a lowermost second substrate wiring layer, or the chip bumps 230 with the second substrate wiring patterns 420 of the lowermost second substrate wiring layer. For example, the via may pass through the lowermost second substrate insulation pattern 410 from the bottom surface of the second substrate wiring patterns 420 and be connected to the top surface of the conductive posts 350 or the top surface of chip bumps 230. The inner chip 200 may be mounted to the bottom surface of the second redistribution layer 400 using chip bumps 230. An upper portion of the second substrate wiring patterns 420 provided on the second substrate insulation pattern 410 may be a head portion used as a horizontal wiring or pad, and the via of the second substrate wiring patterns 420 may be a tail portion. A width of the tail portion may be less than that of the head portion. The width of the tail portion may decrease as a distance from the head portion of the second substrate wiring patterns 420. In other words, the tail portion may have a tapered shape. The second substrate wiring patterns 420 may have a T-shape.

Second seed/barrier layers may be provided between the second substrate wiring patterns 420 and the second substrate insulation pattern 410. Each of the second seed/barrier layers may cover a bottom surface of the second substrate wiring patterns 420. The second seed/barrier layers may conformally cover the bottom surface of the second substrate wiring patterns 420. The second seed/barrier layers may expose a side surface of the second substrate wiring patterns 420. Alternatively, each of the second seed/barrier layers may cover the bottom surface and the side surface of the second substrate wiring patterns 420. In this case, the second seed/barrier layers may conformally cover the bottom surface and the side surface of the second substrate wiring patterns 420. When the second seed/barrier layers are used as a seed layer, the second seed/ barrier layers may comprise a metal such as gold (Au). In the case where the second seed/barrier layers are used as a barrier layer, the second seed/ barrier layers may comprise a metal such as titanium (Ti) and tantalum (Ta), or comprise a metal nitride such as titanium nitride (TiN) and tantalum nitride (TaN). The second seed/barrier layers may not be provided.

The semiconductor chips 20 may be provided on the interposer substrate 10. The semiconductor chips 20 may be disposed on the second redistribution layer 400. Each of the semiconductor chips 20 may comprise a portion vertically overlapped with at least a portion of the inner chip 200 and another portion vertically overlapped with the conductive posts 350. In some implementations, the arrangement of the semiconductor chips 20 may be varied according to a wiring layout of the second redistribution layer 400. Each of the semiconductor chips 20 may comprise a second base layer 510 and a second wiring layer 520.

The second base layer 510 may comprise a semiconductor substrate. For example, the second base layer 510 may be a semiconductor substrate, such as a semiconductor wafer. The second base layer 510 may be a silicon (Si) substrate, a silicon-on-insulator (SOI) substrate, a germanium (Ge) substrate, a germanium-on-insulator (GOI) substrate, a silicon-germanium (SiGe) substrate, a Group 3-5 semiconductor substrate, or a substrate of an epitaxial thin film formed by selective epitaxial growth (SEG). The second base layer 510 may comprise, for example, at least one of silicon (Si), germanium (Ge), silicon-germanium (SiGe), gallium arsenide (GaAs), indium gallium arsenide (InGaAs), aluminum gallium arsenide (AlGaAs), or mixtures thereof. An integrated circuit may be provided on a bottom surface of the second base layer 510. The integrated circuit may comprise a logic circuit or a memory circuit. The semiconductor chips 20 may be logic chips or memory chips. In some implementations, the semiconductor chips 20 may comprise a logic chip, a memory chip, other semiconductor chips including various integrated devices, or passive devices. The integrated circuits of the semiconductor chips 20 has may be the same as each other or different from each other. In other words, the semiconductor chips 20 may be semiconductor chips of the same kind as one another or semiconductor chips of different kinds. A bottom surface of the each of the semiconductor chips 20 may be an active surface, and a top surface of the each of the semiconductor chips 20 may be a back surface. In other words, the semiconductor chips 20 may be disposed on the second redistribution layer 400 in a face down manner.

The second wiring layer 520 may be disposed on the bottom surface of the second base layer 510. For example, the second wiring layer 520 may comprise a second chip insulation pattern 522 and a second chip wiring pattern 524, which are formed on the bottom surface of the second base layer 510. The second wiring layer 520 may include a circuit pattern or a protective layer, as necessary.

The second chip insulation pattern 522 may cover the integrated circuit on the bottom surface of the second base layer 510. The second chip insulation pattern 522 may comprise an insulating material. For example, the second chip insulation pattern 522 may comprise silicon oxide (SiO), silicon nitride (SiN), silicon oxynitride (SiON), silicon carbonitride (SiCN), or an insulating polymer. Alternatively, the second chip insulation pattern 522 may comprise an insulating polymer or a photosensitive insulating material (PID). For example, the photosensitive insulating material may include at least one of a photosensitive polyimide, a polybenzoxazole, a phenolic polymer, and a benzocyclobutene-based polymer.

The second chip wiring pattern 524 may be provided in the second chip insulation pattern 522. The second chip wiring pattern 524 may be electrically connected to the integrated circuit formed on the bottom surface of the second base layer 510. The second chip wiring pattern 524 may comprise a conductive material. For example, the second chip wiring pattern 524 may comprise copper (Cu) or aluminum (Al).

The semiconductor chips 20 may include chip pads 526 provided on the bottom surface thereof. The chip pads 526 may be disposed on the bottom surface of the semiconductor chips 20, i.e., the bottom surface of the second wiring layer 520. The chip pads 526 may be exposed on the bottom surface of the semiconductor chips 20. The chip pads 526 may be electrically connected with the integrated circuit formed in the bottom surface of the second base layer 510 through the second chip wiring pattern 524 in the second wiring layer 520.

The semiconductor chips 20 may be mounted on the interposer substrate 10. For example, the semiconductor chips 20 may be mounted on the second redistribution layer 400 in a flip chip manner. More particularly, the semiconductor chips 20 may be electrically connected to the substrate pads of the second redistribution layer 400 through chip connection terminals 530. The chip connection terminals 530 may be provided between the chip pads 526 and the substrate pads of the second redistribution layer 400. The semiconductor chips 20 may be electrically connected to each other through the chip connection terminals 530, the second redistribution layer 400, and the inner chip 200. Alternatively, the semiconductor chips 20 may be electrically connected to a circuit or element of the inner chip 200 through the chip connection terminals 530 and the second redistribution layer 400. The semiconductor chips 20 may be electrically connected to the first redistribution layer 100 through the chip connection terminals 530, the second redistribution layer 400, and the conductive posts 350.

A second molding layer 30 may be provided on the interposer substrate 10. The second molding layer 30 may surround the semiconductor chips 20 on the second redistribution layer 400. The second molding layer 30 may cover the semiconductor chips 20. Alternatively, the top surface of the semiconductor chips 20 may be exposed on a top surface of the second molding layer 30. The second molding layer 30 may fill a space between the semiconductor chips 20 and the second redistribution layer 400. The second molding layer 30 may surround the chip connection terminals 530 below the semiconductor chips 20. The second molding layer 30 may comprise a molding member. The molding member may comprise, for example, an insulating polymeric material such as an epoxy molding compound (EMC) or an Ajinomoto build-up film (ABF).

Implementations below are described using the same reference numerals or symbols as those described in implementations of FIGS. 1 to 8, and for convenience of description, repeated description thereof may be omitted. Differences between implementations below and those of FIGS. 1 to 8 will be mainly described.

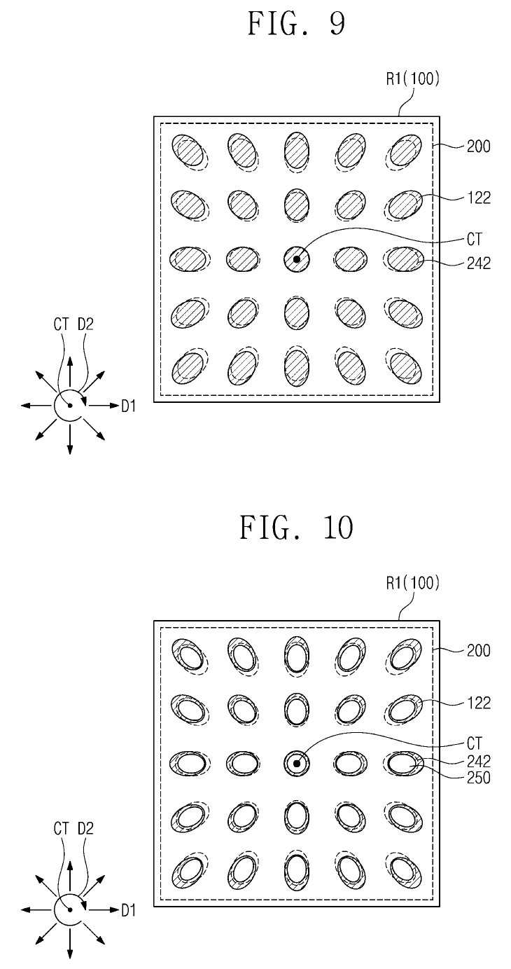

FIGS. 9 and 10 are plan views for illustrating an interposer substrate and an inner chip of a semiconductor package according to some implementations.

Although FIG. 8 shows that the first pads 122 and the chip back pads 242 are vertically aligned and overlap with each other in a plan view.

Referring to FIGS. 1 and 9, a planar shape of the inner chip 200 may be smaller than the planar shapes of the first regions R1 of the first redistribution layer 100. In some examples, in a plan view, the inner chip 200 may be provided inside the first region R1.

The first pads 122 and chip back pads 242 may partially overlap with each other, in a plan view. More specifically, referring to a pair of first pad 122 and the chip back pad 242 corresponding to each other, the first pad 122 may partially overlap with the chip back pad 242. The first pads 122 may be shifted in the first direction D1 from the chip back pad 242. In the pair of first pad 122 and chip back pad 242, the chip back pad 242 may be provided closer from the center CT of the inner chip 200 than the first pad 122. At this time, an area where the chip back pad 242 and the first pad 122 overlap may be 50% to 90% of an area of the chip back pads 242 or an area of the first pads 122. Among the pairs of the first pads 122 and the chip back pads 242, a pair provided farther from the center CT of the inner chip 200 may have a larger distance by which the first pad 122 and the chip back pad 242 are shifted.

Referring to FIGS. 1 and 10, the inner chip terminals 250 may connect the chip back pads 242 and the first pads 122. When the inner chip terminals 250 are coupled to the first pads 122 and the chip back pads 242 by a reflow process, a planar shape of the inner chip terminal 250 may follow a planar shape of an area where the chip back pad 242 and the first pads 122 overlap. For example, depending on an area where the chip back pads 242 and the first pads 122 overlap, the planar shape of the inner chip terminals 250 may have a circle or an ellipse.

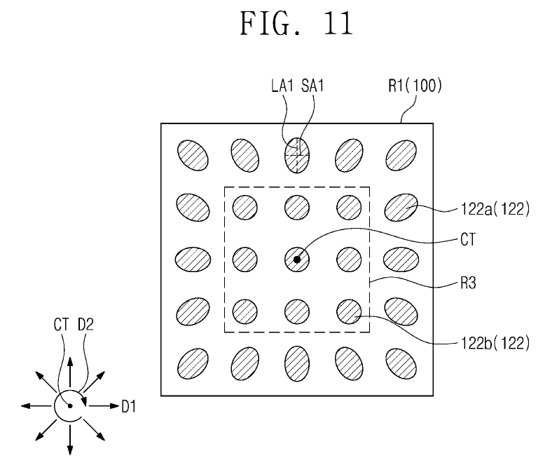

FIG. 11 is a plan view for illustrating an interposer substrate of a semiconductor package according to some implementations. FIG. 11 corresponds to a plan view of a first region R1 of a first redistribution layer 100 of the interposer substrate 10.

Referring to FIGS. 1 and 11, the top surface of the first redistribution layer 100 may comprise the first region R1, the second region R2, and a third region R3. The first region R1 and the third region R3 may be regions where the inner chip 200 is mounted on the first redistribution layer 100. The third region R3 may be provided inside the first region R1. The first region R1 may surround the third region R3. The center CT of the inner chip 200 may be provided on the third region R3.

The first pads 122 may comprise first sub pads 122a and second sub pads 122b. The first sub-pads 122a may be pads provided on the first region R1 among the first pads 122. The second sub-pads 122b may be pads provided on the third region R3 among the first pads 122.

Each of the first sub-pads 122a may have a major axis LA1 and a minor axis SA1, in a plan view. The major axis LA1 and the minor axis SA1 may be parallel to the top surface of the first redistribution layer 100. In a plan view, the major axis LA1 of each of the first sub-pads 122a maybe toward the center CT. The major axis LA1 of the each of the first sub-pads 122a may be along the first direction D1, and the minor axis SA1 of the each of first sub-pats 122a may be along the second direction D2. Lengths of the major axes LA1 of the first sub-pads 122a may increase as the first sub-pads 122a are positioned farther away from the center CT. A planar shape of the each of the first pads 122 may be an elliptical shape or a rectangle having the major axis LA1 and the minor axis SA1.

For the second sub pads 122b provided on the third region R3, a length of a major axis and that of a minor axis of the second sub pad 122b may be equal to each other. That is, the second sub-pads 122b may have a circular planar shape. Widths of the second sub-pads 122b may be substantially the same or similar to the lengths of the minor axes SA1 of the first sub-pads 122a.

Locations of the chip back pads 242 may correspond to locations of the first pads 122 of the first redistribution layer 100. The planar shape of each of the chip back pads 242 may be substantially the same or similar to that of each of the first pads 122. For example, each of the chip back pads 242 provided in a center region of the bottom surface of the inner chip 200 may have a circular planar shape, and each of the chip back pads 242 provided in an edge region of the bottom surface of the inner chip 200 may have an elliptical or rectangular planar shape whose major axis toward the center CT of the inner chip 200. The center region may correspond to the third region R3, and the edge region may correspond to a first region R1.

Locations of the inner chip terminals 250 may correspond to locations of the first pads 122 and the chip back pads 242. A planar shape of each of the inner chip terminals 250 may be substantially the same as or similar to the planar shape of the each of the first pads 122 and the planar shapes of the each of the chip back pads 242. For example, each of the inner chip terminals 250 provided in the center region of the bottom surface of the inner chip 200 may have a circular planar shape, and each of the inner chip terminals 250 provided in the edge region of the bottom surface of the inner chips 200 may have an elliptical or rectangular planar shape with the major axis toward the center CT of the inner chip 20.

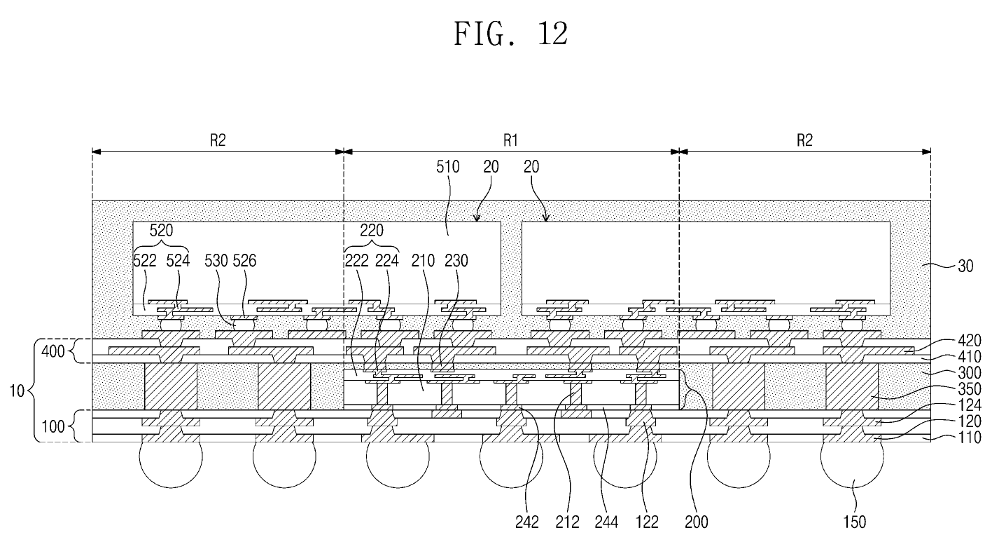

FIG. 12 is a cross-sectional view for illustrating a semiconductor package according to some implementations.

Referring to FIG. 12, the first redistribution layer 100 may include at least one first substrate wiring layer comprising the first substrate insulation pattern 110 and the first substrate wiring pattern 120 on the first substrate insulation pattern 110.

The first substrate wiring patterns 120 may be provided below the first substrate insulation pattern 110. The first substrate wiring patterns 120 may extend horizontally on the first substrate insulation pattern 110. The first substrate wiring patterns 120 may be provided on the bottom surface of the first substrate insulation pattern 110. The first substrate wiring patterns 120 may protrude from the bottom surface of the first substrate insulation pattern 110. One of the first substrate wiring patterns 120 of the first substrate wiring layers may be electrically connected with another adjacent one of the first substrate wiring pattern 120 of the first substrate wiring layers. The first substrate wiring patterns 120 on one of the first substrate insulation patterns 110 may be covered by another one of the first substrate insulation patterns 110. The first substrate wiring patterns 120 of the lowermost first substrate wiring layer may be exposed on the bottom surface of the first substrate insulation pattern 110 and may serve as external pads provided on the bottom surface of first redistribution layer 100. Alternatively, the first redistribution layer 100 may comprise separate external pads connected to the first substrate wiring patterns 120 of the lowermost first substrate wiring layer.

The first substrate wiring patterns 120 may have a damascene structure. For example, each or at least some of the first substrate wiring patterns 120 may comprise a via protruding from a top surface thereof. For example, the via may extend from the top surface of one of the first substrate wiring patterns 120, and may penetrate through the first substrate insulation pattern 110 to be connected to another one of the first substrate wiring patterns 120 provided thereon. Each or at least some of the first substrate wiring patterns 120 may have an inverted T-shape.

The inner chip 200 may be provided on the first redistribution layer 100. The inner chip 200 may be in contact with the top surface of the first redistribution layer 100. The inner chip terminals may be not provided between the first redistribution layer 100 and the inner chip 200.

The first substrate wiring patterns 120 of the uppermost first substrate wiring layer may penetrate the first substrate insulation pattern 110 to be connected to bottom surfaces of the chip back pads 242 of the inner chip 200 or bottom surfaces of the conductive posts 350.

Some of the first substrate wiring patterns 120 connected to the chip back pads 242 of the inner chip 200 may correspond to first pads of the first redistribution layer 100, and some of the first substrate wiring patterns 120 connected to the conductive posts 350 may correspond to second pads of the first redistribution layers 100.

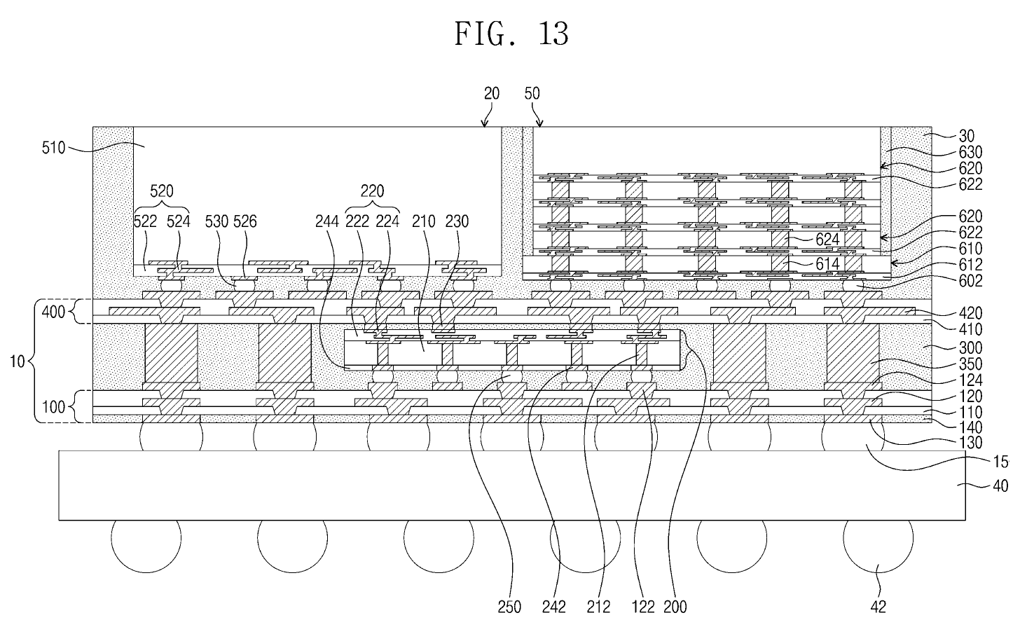

FIG. 13 is a cross-sectional view for illustrating a semiconductor package according to some implementations.

Referring to FIG. 13, a semiconductor package may comprise a chip stack 50. Hereinafter, the semiconductor chip 20 directly mounted on a second redistribution layer 400 will be referred to as a first semiconductor chip 20.

The first semiconductor chip 20 may comprise a logic circuit. In other words, the first semiconductor chip 20 may be a logic chip. In some examples, the first semiconductor chip 20 may comprise a graphics processing unit.

The chip stack 50 may be disposed on the second redistribution layer 400. The chip stack 50 may be spaced apart from the first semiconductor chip 20. A thickness of the first semiconductor chip 20 may be greater than that of semiconductor chips 610, 620 of the chip stack 50. A top surface of the chip stack 50 may be provided at the same or higher level as the top surface of the first semiconductor chip 20.

The chip stack 50 may include a base substrate, second semiconductor chips 620 stacked on the base substrate, and a third molding layer 630 surrounding the second semiconductor chips 620. Hereinafter, the chip stack 50 will be described in detail.

The base substrate may be a base semiconductor chip 610. For example, the base substrate may be a wafer-level semiconductor substrate made of a semiconductor material such as silicon (Si). Hereinafter, the base semiconductor chip 610 refers to the same components as the base substrate, and the same reference numerals as those of the base semiconductor chip and the base substrate may be used.

The base semiconductor chip 610 may comprise a third wiring layer 612 and first chip vias 614. The third wiring layer 612 may be provided on a bottom surface of the base semiconductor chip 610. The third wiring layer 612 may include an integrated circuit. For example, the third wiring layer 612 may be a memory circuit. That is, the base semiconductor chip 610 may be a memory chip such as DRAM, SRAM, MRAM, or flash memory. Alternatively, the base semiconductor chip 610 may be a logic chip. The first chip vias 614 may penetrate the base semiconductor chip 610 in a direction perpendicular to the top surface of the second redistribution layer 400. The first chip vias 614 and the third wiring layer 612 may be electrically connected. A bottom surface of the base semiconductor chip 610 may be an active surface. In some implementations, the base substrate may be a wiring substrate that does not include the base semiconductor chip 610.

The second semiconductor chip 620 may be mounted on the base semiconductor chip 610. The second semiconductor chip 620 may form a chip on wafer (COW) structure with the base semiconductor chip 610. A width of the second semiconductor chip 620 may be less than that of the base semiconductor chip 610.

The second semiconductor chip 620 may comprise a fourth wiring layer 622 and second chip vias 624. The fourth wiring layer 622 may comprise a memory circuit. That is, the second semiconductor chip 620 may be a memory chip such as DRAM, SRAM, MRAM, or flash memory. The fourth wiring layer 622 may comprise the same circuit as the third wiring layer 612. The second chip vias 624 may penetrate the second semiconductor chip 620 in the direction perpendicular to the top surface of the second redistribution layer 400. The second chip vias 624 and the fourth wiring layer 622 may be electrically connected. A bottom surface of the second semiconductor chip 620 may be an active surface.

The second semiconductor chip 620 may be bonded to the base semiconductor chip 610. For example, pads of the fourth wiring layer 622 of the second semiconductor chip 620 may be in contact with a top surface of the first chip vias 614 exposed on a top surface of a base semiconductor chip 610. Alternatively, the second semiconductor chip 620 may be mounted to the top surface of the first chip vias 614 using terminals provided on the pads of the fourth wiring layer 622.

The second semiconductor chip 620 may be provided in plural. For example, the plurality of second semiconductor chips 620 may be stacked on the base semiconductor chip 610. Four to thirty-two of the second semiconductor chips 620 may be stacked. At this time, uppermost one of the second semiconductor chips 620 may not comprise the second chip vias 624. Further, a thickness of the uppermost second semiconductor chip 620 may be greater than that of another of the second semiconductor chips 620 disposed therebelow.

Two adjacent ones of the second semiconductor chips may be bonded to each other. For example, pads of the fourth wiring layer 622 of each of the second semiconductor chips 620 may be in contact with a top surface of the second chip vias 624 that are exposed on a top surface of the second semiconductor chip 620 positioned therebelow. Alternatively, the second semiconductor chips 620 may be mounted to the top surface of second chip vias 624 using terminals provided on the pads of fourth wiring layer 622.

A third molding layer 630 may be disposed on the top surface of the base semiconductor chip 610. The third molding layer 630 may cover the base semiconductor chip 610 and may surround the second semiconductor chips 620. A top surface of the third molding layer 630 may be coplanar with a top surface of the uppermost second semiconductor chip 620, and the uppermost second semiconductor chip 620 may be exposed on the top surface of the third molding layer 630. The third molding layer 630 may comprise an insulating polymer material, such as an epoxy molding compound (EMC).

Connection terminals 602 may be provided on a bottom surface of the chip stack 50, that is, the bottom surface of the third wiring layer 612. The chip stack 50 may be connected to the second redistribution layer 400 through the connection terminals 602.

The interposer substrate 10 may be mounted to a module substrate 40. The module substrate 40 may comprise a printed circuit board (PCB) or the like. The interposer substrate 10 may be mounted to the module substrate 40 using the external terminals 150. A bottom surface of the module substrate 40 may be provided with substrate terminals 42, such as solder balls.

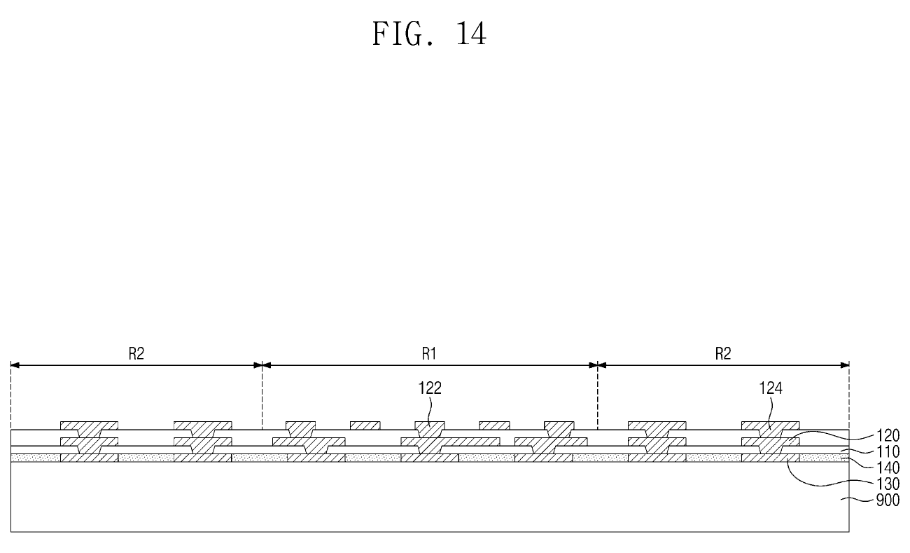

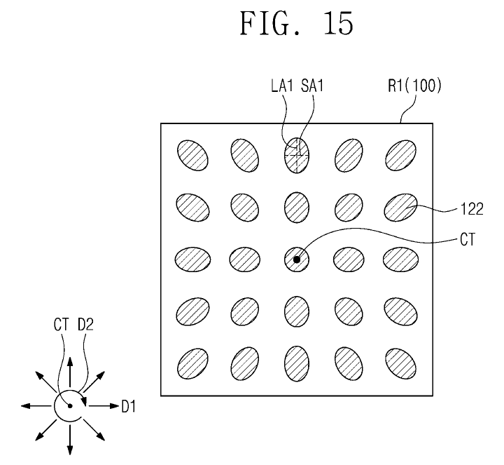

FIGS. 14 to 22 are drawings for explaining a method of fabricating a semiconductor package according to some implementations. FIGS. 14, 16, 18, 20, and 22 correspond to cross-sectional views of a semiconductor package, and FIGS. 15, 17, 19, and 21 correspond to plan views relative to FIGS. 14,16, 18, and 20, respectively. FIGS. 15, 17, 19 and 21 show a top surface of a first redistribution layer 100 and a bottom surface of an inner chip 200 on a same plane.

Referring to FIGS. 14 and 15, a carrier substrate 900 may be provided. The carrier substrate 900 may be an insulating substrate including metal, glass, organic insulator, or polymer.

A pad layer may be formed on the carrier substrate 900. For example, an insulating layer may be formed on the carrier substrate 900 and a substrate protection layer 140 may be formed by patterning the insulating layer. The patterning process may comprise an etching process or an exposure/development process. External pads 130 may be formed by filling a conductive material into patterns of the substrate protection layer 140. The process of forming the external pads 130 may include a plating process. Alternatively, a conductive layer may be formed on the carrier substrate 900 and the external pads 130 may be formed by patterning the conductive layer. Then, an insulating layer covering the external pads 130 may be formed on the carrier substrate 900 and the substrate protection layer 140 may be formed by a thinning process performed on the insulating layer.

A first substrate insulation pattern 110 may be formed on the substrate protection layer 140. The first substrate insulation pattern 110 may be formed by a deposition process or a coating process. The first substrate insulation pattern 110 may cover the substrate protection layer 140 and the external pads 130. First substrate wiring patterns 120 may be formed on the first substrate insulation pattern 110. For example, the first substrate insulation pattern 110 may be patterned to form openings exposing the external pads 130. A seed layer conformally covering a top surface of the first substrate insulation patterns 110 and inner and bottom surfaces of the openings may be formed. A plating process may be performed on the seed layer as a seed to form a conductive layer that cover the first substrate insulation patterns 110 and filling the openings. The conductive layer and the seed layer may be patterned to form the first substrate wiring patterns 120. As described above, one first substrate wiring layer including the first substrate insulation pattern 110 and the first substrate wiring patterns 120 in the first substrate insulation patterns 110 may be formed on the substrate protection layer 140 and the external pads 130. The step of forming the first substrate wiring layer may be repeatedly performed to form the first redistribution layer 100.

The first substrate wiring patterns 120 of the uppermost first substrate wiring layers may comprise first pads 122 to which an inner chip 200 described later is connected or second pads 124 to which conductive posts 350 are connected. A top surface of the first redistribution layer 100 may comprise a first region R1 and a second region R2. The first region R1 may be a region where the inner chip 200 is mounted on the first redistribution layer 100. The second region R2 may be a region remaining on the top surface of the first redistribution layer 100 except for the first region R1, and may be a region where the conductive posts 350 are connected to the first redistribution layer 100.

Each of the first pads 122 may have a planar shape in which a width in one direction is greater than that in the other direction. More specifically, the each of the first pads 122 may have a major axis LA1 and a minor axis SA1, in a plan view. In a plan view, the major axis LA1 of the each of the first pads 122 may be directed toward a center CT of the first region R1. The major axis LA1 of the each of the first pads 122 may be along the first direction D1, and the minor axis SA1 of the each of first pads 122 may be along the second direction D2. The minor axis SA1 of the each of the first pads 122 may be arranged along a concentric circle relative to the center CT of the first region R1. Lengths of the major axes LA1 of the first pads 122 may increase as the first pads 122 are positioned farther away from the center CT of the first region R1.

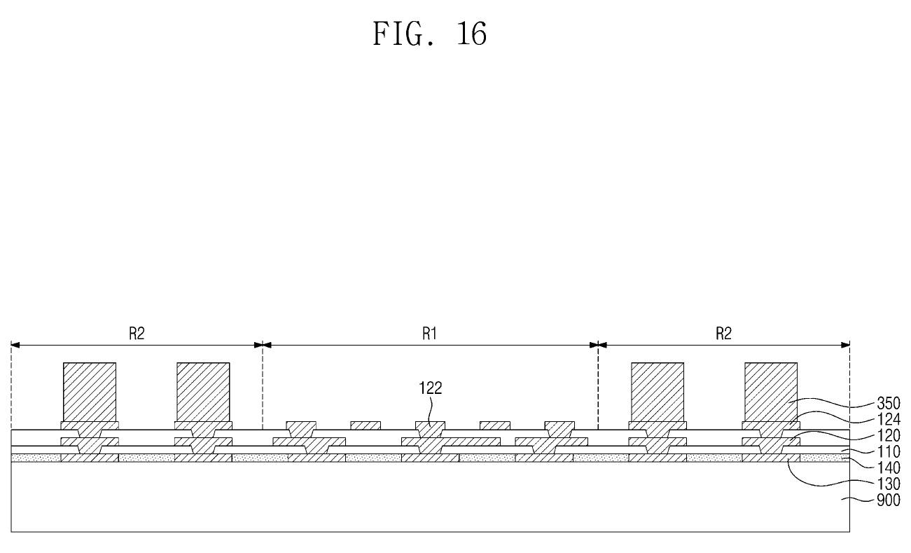

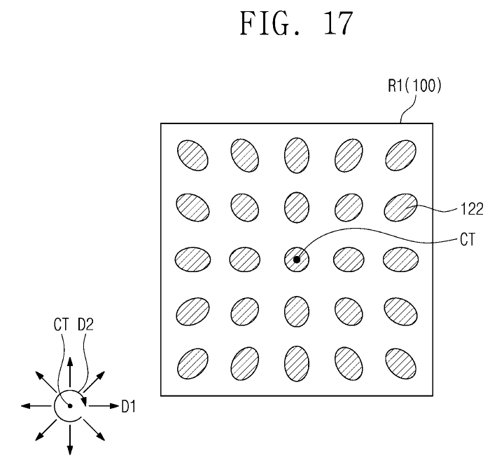

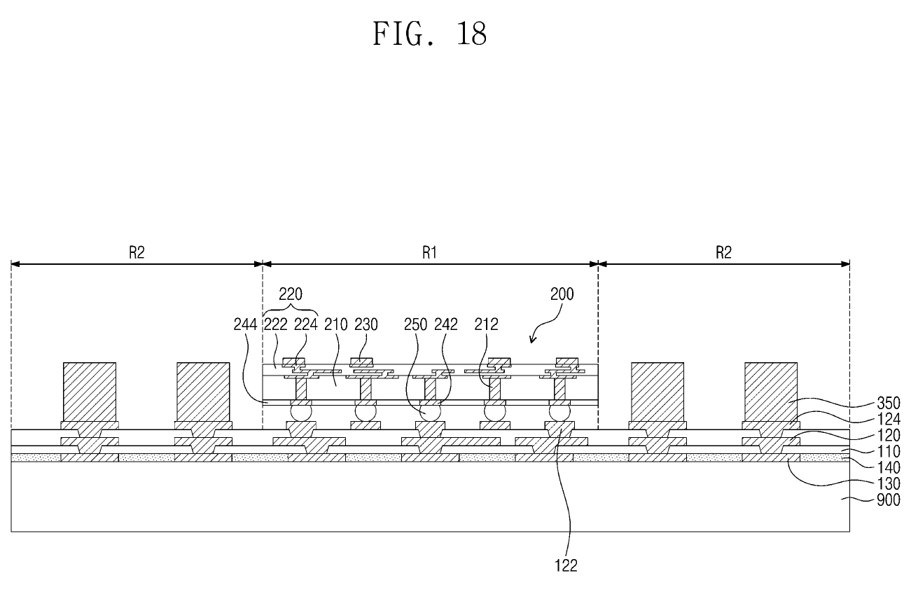

Referring to FIGS. 16 and 17, the conductive posts 350 may be formed. More specifically, a sacrificial layer may be formed on the first redistribution layer 100. The sacrificial layer may cover the top surface of the first redistribution layer 100. The sacrificial layer may be patterned to form holes which expose the second pads 124 of the first redistribution layer 100. The conductive posts 350 may be formed by filling the holes with conductive material. For example, a seed layer conformally covering a top surface of the sacrificial layer, a bottom surface and an inner surface of the holes may be formed, and a plating process may be performed using the seed layer as a seed to form the conductive posts 350 that fill the holes. Alternatively, the conductive posts 350 may be formed by performing a plating process on a top surface of the second pads 124 exposed on the bottom surface of the holes. The sacrificial layer may then be removed.

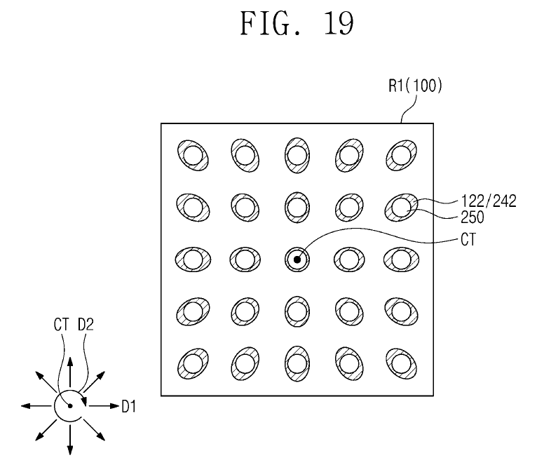

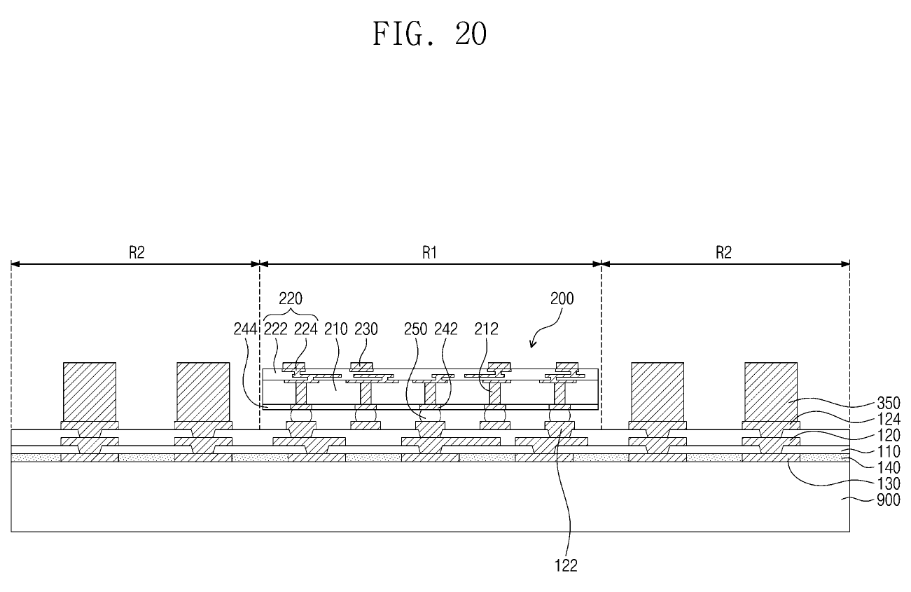

Referring to FIGS. 18 and 19, the inner chip 200 may be provided. The inner chip 200 may be the same as or similar to the inner chip 200 described with reference to FIGS. 1 to 13.

Each of chip back pads 242 of the inner chip 200 may have a planar shape in which a width in one direction is greater than that in other direction. More specifically, the each of the chip back pads 242 may have a major axis and a minor axis, in a plan view. In a plan view, the major axis of the each of the chip back pads 242 may be directed toward the center CT of the inner chip 200. The major axis of the each of the chip back pads 242 may be along the first direction D1, and the minor axis of the each of chip back pads 142 may be along the second direction D2. The minor axis of the each of the chip back pads 242 may be arranged along a concentric circle relative to the center CT of the inner chip 200. Lengths of the major axes of the chip back pads 242 may increase as the chip back pads 242 are positioned farther away from the center CT of the inner chip 200. Inner chip terminals 250 may be provided on the chip back pads 242 of the inner chip 200.

The inner chip 200 may be positioned on the first redistribution layer 100. At this time, the inner chip terminals 250 may be face the first redistribution layer 100. The inner chip 200 may be aligned on the first region R1 of the first redistribution layer 100. For example, the first redistribution layer 100 and the inner chip 200 may be aligned such that the chip back pads 242 of the inner chip 200 and the first pads 122 of the first redistribution layer 100 face each other.

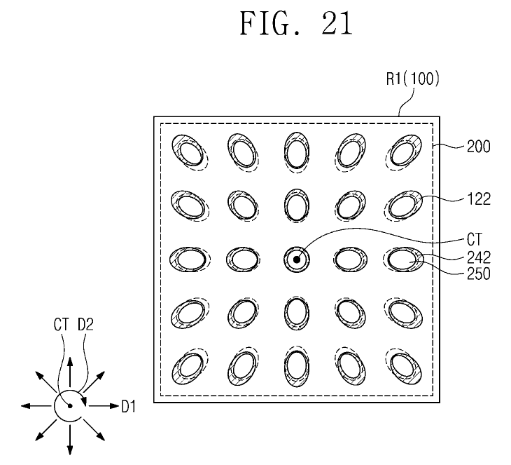

Referring to FIGS. 20 and 21, the inner chip 200 may be mounted on the first redistribution layer 100. For example, the first redistribution layer 100 and the inner chip 200 may be closer to each other such that the inner chip terminals 250 contact the first pads 122. Thereafter, a reflow process may be performed on the inner chip terminals 250 such that the inner chip terminals 250 may be bonded to the first pads 122.

A coefficient of thermal expansion of the inner chip 200 may be different from that of the first redistribution layer 100. The first redistribution layer 100 and the inner chip 200 may expand or contract with changes in temperature. In some examples, during the reflow process, heat may be applied to the first redistribution layer 100 and the inner chip 200. FIG. 21 illustrates an example where the coefficient of thermal expansion of the inner chip 200 is less than that of the first redistribution layer 100. The first redistribution layer 100 and the inner chip 200 may be expanded by the reflow process. At this time, an extent to which the inner chip 200 expands may be less than an extent to which first redistribution layer 100 expands. Therefore, a planar shape of the inner chip 200 may be larger than that of the first regions R1. Depending on the difference in the extent of expansion of the inner chip 200 and the extent of expansion of the first redistribution layer 100, the chip back pads 242 and the first pads 122 may be misaligned. For example, as shown in FIG. 21, with the expansion of the inner chip 200, the chip back pads 242 may be moved horizontally in a direction away from the center CT of the inner chip 200. As the expansion of the first redistribution layer 100, the first pads 122 may be moved horizontally in the direction away from the center CT of inner chip 200. As the extent of expansion of the first redistribution layer 100 expands and the extent of expansion of the inner chip 200 are different from each other, the chip back pads 242 may be moved horizontally from the first pads 122 when viewed relative to the first pads 112. For example, the movement of each of the chip back pads 242 may proceed along the major axis of the first pad 122 provided below it. From the perspective of the first pads 122, each of the chip back pads 242 may be shifted from the first pad 122 provided therebelow in the direction toward the center CT of the inner chip 200. The first pads 122 may be shifted from the chip back pads 242 in the direction away from the center CT of the inner chip 200. Among pairs of the first pads 122 and the chip back pads 242, a pair farther provided from the center CT of the inner chip 200 may have a greater shift distance. The above is described as some examples of the case where the coefficient of thermal expansion of the inner chip 200 is less than that of the first redistribution layer 100. In some implementations, when the coefficient of thermal expansion of the inner chip 200 is greater than that of the first redistribution layer 100, the first redistribution layer 100 and the inner chip 200 may be expanded by the reflow process. As the expansion of the first redistribution layer 100, the first pads 122 may be moved horizontally in the direction away from the center CT of the inner chip 200. Each of the chip back pads 242 may be shifted from the first pad 122 provided below it in the direction away from the center CT of the inner chip 200. Movement of each of the chip back pads 242 may proceed along the major axis of the first pad 122 provided below it.

According to implementations of the invention, the first pads 122 and the chip back pads 242 may have an elliptical planar shape with the major axis in the direction away from the center CT of the inner chip 200. Although the first pads 122 and the chip back pads 242 are shifted from each other by contraction or expansion of the first redistribution layer 100 and the inner chip 200, the first pads 112 and the chip back pads 242 may at least partially overlap. That is, even during a high-temperature process, it may be easy to contact the inner chip terminals 250 to the first pads 122, and the inner chip terminal 250 may vertically connect the chip back pads 242 and the first pads 112 on areas where the chip back pad 242 and the first pads 122 overlap. A method of manufacturing a semiconductor package with less occurrence of defects, such as disconnection or contact failure of the inner chip terminals 250 that may occur due to complete misalignment of the chip back pad 242 and the first pads 122, may be provided. In addition, a method for manufacturing a semiconductor package in which a temperature range of a process performed in a manufacturing process of the semiconductor package is large may be provided.

Referring again to FIGS. 20 and 21, Due to a wettability of reflowed solder material, the inner chip terminals 250 may be formed such that their planar shapes are the same as or similar to the planar shape of the first pads 122 or the planar shapes of the chip back pads 242. For example, depending on the area where the chip back pads 242 and the first pads 122 overlap, the planar shape of the inner chip terminals 250 may be a circle or an ellipse.

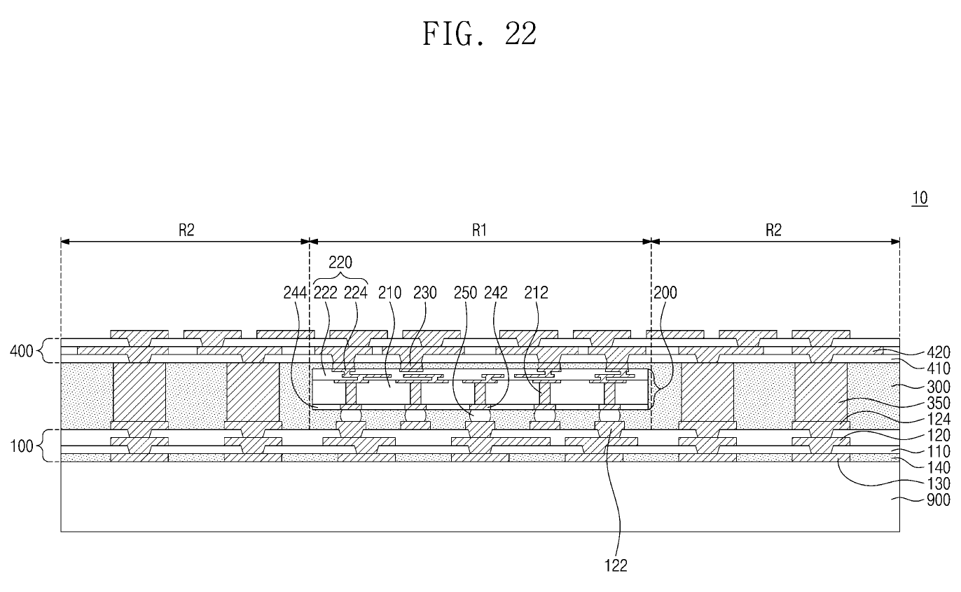

Referring to FIG. 22, a first molding layer 300 may be formed on the first redistribution layer 100. For example, after depositing or applying an insulating layer covering the inner chip 200 and the conductive posts 350 on the first redistribution layer 100, the insulating layer may be cured to form the first molding layer 300. The inner chip 200 and the conductive posts 350 may be embedded in the first molding layer 300 on the first redistribution layer 100. Then, a planarization process may be performed on the first molding layer 300, so that a top surface of chip bumps 230 of the inner chip 200 and top surfaces of the conductive posts 350 are exposed on a top surface of the first molding layer 300. The planarization process may comprise a chemical mechanical polishing (CMP) process. The first molding layer 300 may comprise a molding member. The molding member may comprise, for example, an insulating polymeric material such as an epoxy molding compound (EMC) or an Ajinomoto build-up film (ABF).

A second substrate insulation pattern 410 may be formed on the first molding layer 300. The second substrate insulation pattern 410 may be formed by a deposition process or a coating process. The second substrate insulation pattern 410 may cover the conductive posts 350, the first molding layer 300, and the chip bumps 230. Second substrate wiring patterns 420 may be formed on the second substrate insulation pattern 410. For example, the second substrate insulation pattern 410 may be patterned to form openings exposing the conductive posts 350 and the chip bumps 230. A plating process may be performed with a seed layer conformally formed on a top surface of the second substrate insulation patterns 410 and inner and bottom surfaces of the openings as a seed to form a conductive layer covering the second substrate insulation patterns 410 and filling the openings. The conductive layer may be patterned to form the second substrate wiring pattern 420.

As described above, a second substrate wiring layer including the second substrate insulation pattern 410 and the second substrate wiring pattern 420 in the second substrate insulation patterns 410 may be formed on the first molding layer 300. The step of forming the second substrate wiring layer may be repeatedly performed to form a second redistribution layer 400. The second substrate wiring pattern 420 provided in the uppermost second substrate wiring layer may be substrate pads on which semiconductor chips 20 are mounted.

Referring again to FIG. 1, the semiconductor chips 20 may be mounted on the second redistribution layer 400. The semiconductor chips 20 may be mounted in a flip-chip manner.

A second molding layer 30 may be formed on the second redistribution layer 400. For example, an insulating layer may be formed to cover the semiconductor chips 20 on the second redistribution layer 400, thereafter the insulating layer may be cured to form the second molding layer 30. The semiconductor chips 20 may be embedded in the second molding layer 30 on the second redistribution layer 400.

Then, a singulation process may be performed on the structure on the carrier substrate 900. In some implementations, the singulation process may be performed after the interposer substrate 10 is formed. The carrier substrate 900 may be removed. The carrier substrate 900 may be removed to expose the first redistribution layer 100. External terminals 150 may be provided on a bottom surface of the external pads 130 that are exposed. The external terminals 150 may include solder balls or solder bumps.

In some examples of the semiconductor package, the first pads and the chip back pads may overlap each other even if the first pads and the chip back pads are shifted from each other by contraction or expansion of the first redistribution layer and the inner chip. That is, the inner chip terminals may not be disconnected from the first pads or chip back pads due to misalignment of the first pads and chip back pads. Therefore, a semiconductor package with improved structural stability may be provided, and an operating temperature range of the semiconductor package or a temperature range of a process performed in a manufacturing process of the semiconductor package may also be expanded.

In general, in some aspects, the present disclosure provides a method for manufacturing a semiconductor package. The method can include forming a first redistribution layer, a top surface of the first redistribution layer comprising a first region in which first pads are provided and a second region surrounding the first region and in which second pads are provided; forming conductive posts connected to the second pads on the first redistribution layer; providing chip terminals on chip pads of an inner chip; mounting the inner chip on the first redistribution layers, so that the chip terminals are connected with the first pads; forming a molding layer surrounding the conductive posts and the inner chip on a first redistribution layer; forming a second redistribution layer on the molding layer, the second redistribution layer comprising a wiring pattern connected with an active surface of the inner chip and the conductive posts; and mounting a semiconductor chip on the second redistribution layer. Each of the first pads may have a major axis and a minor axis parallel to the top surface of the first redistribution layer and perpendicular to each other. The major axis of the each of the first pads is directed toward a center of the inner chip, in a plan view.

In some implementations, the mounting the inner chip may comprises performing a reflow process on the chip terminals. During the reflow process, the inner chip may expand or contract.

In some implementations, the chip pads of the inner chip may move horizontally in direction away from the center of the inner chip during expansion or contraction of the inner chip.

In some implementations, the movement of the chip pads may be along the major axis of the each of the first pads.

In some implementations, after expansion or contraction of the inner chip, each of the chip pads may at least partially overlap with any one of the first pads.

In some implementations, the major axis of the each of the first pads may be parallel to a first direction away from the center of the inner chip. The minor axis of the each of the first pads may be parallel to a second direction rotating about the center of the inner chip.

In some implementations, each of the first pads may have an elliptical planar shape or rectangular planar shape.

In some implementations, the ratio of the major axis and the minor axis of the each of the first pads may be 1.1:1 to 2.5:1.

In some implementations, lengths of the major axes of the first pads may be increase as the first chip pads are positioned farther away from the center of the inner chip.

In some implementations, a coefficient of thermal expansion of the inner chip may be less than a coefficient of thermal expansion of the first redistribution layer.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. While example implementations of the inventive concept have been particularly shown and described, it will be understood by one of ordinary skill in the art that variations in form and detail may be made therein without departing from the spirit and scope of the attached claims.

While implementations are described above, a person skilled in the art may understand that many modifications and variations are made without departing from the spirit and scope of the inventive concept defined in the following claims. Accordingly, the example implementations of the inventive concept should be considered in all respects as illustrative and not restrictive, with the scope of the inventive concept being indicated by the appended claims.

What is claimed is:

1. A semiconductor package comprising:
a first redistribution layer;
an inner chip on the first redistribution layer;
a plurality of first chip terminals connecting the first redistribution layer and the inner chip;
a molding layer surrounding the inner chip on the first redistribution layer;
a second redistribution layer on the molding layer and including a plurality of first wiring patterns connected to a top surface of the inner chip;
a plurality of conductive posts vertically extending into the molding layer and connecting the first redistribution layer and the second redistribution layer; and
a first semiconductor chip on the second redistribution layer,
wherein each first chip terminal of the plurality of first chip terminals has a first major axis and a first minor axis that are (i) parallel to a top surface of the first redistribution layer and (ii) perpendicular to each other, and
wherein the first major axis of each first chip terminal of the plurality of first chip terminals is directed toward a center of the inner chip, in a plan view.

2. The semiconductor package of claim 1, wherein the first major axis of each first chip terminal of the plurality of first chip terminals is aligned along a respective first axis of a plurality of first axes that extend from the center of the inner chip, and
wherein the first minor axis of each first chip terminal of the plurality of first chip terminals is aligned along a respective second axis of a plurality of second axes that are tangential to a circular path around the center of the inner chip.

3. The semiconductor package of claim 1, wherein each first chip terminal of the plurality of first chip terminals has an elliptical planar shape.

4. The semiconductor package of claim 1, wherein a ratio of the first major axis and the first minor axis of each first chip terminal of the plurality of first chip terminals ranges from 1.1:1 to 2.5:1.

5. The semiconductor package of claim 1, wherein lengths of the plurality of first major axes of the plurality of first chip terminals increase as the plurality of first chip terminals are positioned farther away from the center of the inner chip.

6. The semiconductor package of claim 1, wherein the inner chip has a coefficient of thermal expansion that is less than a coefficient of thermal expansion of the first redistribution layer.

7. The semiconductor package of claim 1, wherein the first redistribution layer comprises:
a plurality of first substrate pads on the top surface of the first redistribution layer and connected to the first chip terminals; and
a plurality of second substrate pads on the top surface of the first redistribution layer and connected to the second substrate pads,
wherein each first substrate pad of the plurality of first substrate pads has an elliptical planar shape or a rectangular planar shape, and
wherein each second substrate pad of the plurality of second substrate pads has a circular planar shape, a square planar shape, or a polygonal planar shape.

8. The semiconductor package of claim 7, wherein each first substrate pad of the plurality of first substrate pads has a second major axis and a second minor axis that are (i) parallel to the top surface of the first redistribution layer and (ii) perpendicular to each other, and
wherein the second major axis of each first substrate pad of the plurality of first substrate pads is directed toward the center of the inner chip, in a plan view.

9. The semiconductor package of claim 1, wherein the inner chip comprises a plurality of chip pads on a bottom surface of the inner chip, the plurality of first chip terminals being connected to the plurality of chip pads,
wherein each chip pad of the plurality of chip pads has a third major axis and a third minor axis that are (i) parallel to the top surface of the first redistribution layer and (ii) perpendicular to each other, and
wherein the third major axis of each chip pad of the plurality of chip pads is directed toward the center of the inner chip, in a plan view.

10. The semiconductor package of claim 9, wherein a top surface of the inner chip is an active surface, and
wherein the inner chip further comprises vias vertically penetrating the inner chip to connect the active surface and the chip pads.

11. The semiconductor package of claim 1, further comprising:
a plurality of second chip terminals connecting the first redistribution layer and the inner chip,
wherein a bottom surface of the inner chip comprises
a first region comprising a plurality of second chip terminals, and
a second region surrounding the first region and comprising the plurality of first chip terminals,
wherein the center of the inner chip is on the first region, and
wherein each second chip terminal of the plurality of second chip terminals has a circular planar shape.

12. The semiconductor package of claim 1, further comprising:
a package substrate below the first redistribution layer; and
a chip stack on the second redistribution layer and horizontally spaced apart from the first semiconductor chip,
wherein the chip stack comprises a plurality of second semiconductor chips that are vertically stacked.

13. A semiconductor package comprising:
a package substrate;
an interposer substrate on the package substrate;
a first semiconductor chip on the interposer substrate; and
a chip stack on the interposer substrate, horizontally spaced apart from the first semiconductor chip, and comprising a plurality of second semiconductor chips that are vertically stacked,
wherein the interposer substrate comprises
a first redistribution layer having a top surface that comprises (i) a first region comprising a plurality of first pads and (ii) a second region surrounding the first region and comprising a plurality of second pads,
an inner chip on the first redistribution layer and mounted to the first pads,
a molding layer surrounding the inner chip on the first redistribution layer,
a second redistribution layer on the molding layer and comprising a wiring pattern connected to an active surface of the inner chip, and
a plurality of conductive posts vertically extending into the molding layer and connecting the first redistribution layer and the second redistribution layer, the plurality of conductive posts being connected to the second pads,
wherein each first pad of the plurality of first pads has an elliptical planar shape or a rectangular planar shape, and
wherein each second pad of the plurality of second pads has a circular planar shape or a square planar shape.

14. The semiconductor package of claim 13, wherein each first pad of the plurality of first pads has (i) a first length that is aligned along a respective first axis of a plurality of first axes that extend from a center of the inner chip and (ii) a first width that is aligned along a respective second axis of a plurality of second axes that are tangential to a circular path around the center of the inner chip, and
wherein the first length is greater than the first width.

15. The semiconductor package of claim 14, wherein a ratio of the first length and the first width of each first pad of the plurality of first pads ranges from 1.1:1 to 2.5:1.

16. The semiconductor package of claim 14, wherein the first lengths of the plurality of first pads increase as the plurality of first pads are positioned farther away from the center of the inner chip.

17. The semiconductor package of claim 13, wherein the inner chip is mounted to the plurality of first pads using a plurality of chip terminals,
wherein each chip terminal of the plurality of chip terminals has a major axis and a minor axis that are (i) parallel to the top surface of the first redistribution layer and (ii) perpendicular to each other, and
wherein the major axis of the each chip terminal of the plurality of chip terminals is directed toward a center of the inner chip.

18. The semiconductor package of claim 13, wherein the inner chip has a coefficient of thermal expansion that is less than a coefficient of thermal expansion of the first redistribution layer.

19. The semiconductor package of claim 13, wherein the inner chip comprises a bridge chip, a passive device chip, or an integrated voltage regulator (IVR) chip.

20. A semiconductor package comprising:
a first redistribution layer having a top surface that comprises (i) a first region comprising a plurality of first pads and (ii) a second region surrounding the first region and comprising a plurality of second pads;
an inner chip on the first redistribution layer and mounted to the plurality of first pads;
a plurality of chip terminals connecting the first pads and the inner chip;
a molding layer surrounding the inner chip on the first redistribution layer;
a plurality of conductive posts vertically extending into molding layer and connected to the plurality of second pads of the first redistribution layer; and
a second redistribution layer on the molding layer and comprising a wiring pattern connected to (i) an active surface of the inner chip and (ii) the plurality of conductive posts,
wherein each first pad of the plurality of first pads has a major axis and a minor axis is (i) parallel to the top surface of the first redistribution layer and (ii) perpendicular to each other,
wherein the major axis of the each first pad of the plurality of first pads is directed toward a center of the inner chip, in a plan view, and
wherein each second pad of the plurality of second pads has a circular planar shape or a square planar shape.
